(19) United States
(12) Patent Application Publication
(10) Pub. No.: US 2026/0163570 A1
(43) Pub. Date: Jun. 11, 2026

(54) TRANSMITTER WITH DIFFERENTIAL SIGNAL CROSS POINT VOLTAGE CONTROL CIRCUITRY

(71) Applicant: Rambus Inc., San Jose, CA (US)

(72) Inventors: Kumail Khozema Khurram, Amravati (IN); Dhiraj Kumar, Bangaluru (IN)

(21) Appl. No.: 19/404,706

(22) Filed: Dec. 1, 2025

Related U.S. Application Data
(60) Provisional application No. 63/729,551, filed on Dec. 9, 2024.

(51) Int. Cl. H03K 17/56

(52) U.S. Cl. CPC H03K 17/56

(57) ABSTRACT

Technologies for transmitters with differential signal cross point voltage control are described. One transmitter circuit includes a differential driver circuit to generate a differential output signal. The differential driver circuit includes a programmable phase distribution to adjust a differential cross-point ratio of the differential driver circuit. The differential driver circuit includes a plurality of voltage-mode drivers, each voltage-mode driver comprises a pull-up transistor, a pull-down transistor, and a pre-driver with a programmable phase that is individually controlled for each voltage-mode driver such that the plurality of voltage-mode drivers collectively adjust the differential cross-point ratio.

### RELATED APPLICATIONS

This application claims the benefit of U.S. Provisional Patent Application No. 63/729,551, filed Dec. 9, 2024, the contents of which is incorporated by reference in its entirety herein.

### BACKGROUND

Modern computer systems generally include a data storage device, such as a memory component or device. The memory component may be, for example, a random-access memory (RAM) or a dynamic random-access memory (DRAM) device. The memory device includes memory banks made up of memory cells that a memory controller or memory client accesses through a command interface and a data interface within the memory device. The memory devices can be located on a memory module. The memory module can include one or more volatile memory devices.

In high-performance datacenter and client computing, memory sub-systems constantly strive to keep pace with the ever-increasing computational demands. To achieve the necessary memory capacity, dual in-line memory modules (DIMMs) are extensively used. However, the high data rates in modern DIMMs, such as using Double Data Rate 5 (DDR5) Synchronous Dynamic Random-Access Memory (SDRAM), have led to signal integrity challenges, particularly at the memory interface. These challenges include reflections, crosstalk, and electromagnetic interference (EMI), which degrade signal quality and system performance.

To mitigate signal integrity issues, buffer integrated circuits (commonly referred to as buffer chips), like the Register Clock Driver (RCD) and Clock Driver (CKD), are introduced. These buffer chips act as buffers for the command/address (CA) signals, which are single-ended, and the clock signals, which are differential. By buffering these signals, the RCD and CKD chips enhance noise immunity and ensure robust communication between the memory controller and the DRAM devices.

There are several parameters that contribute to reliable transmission of signals between integrated circuits. A critical parameter in ensuring the reliable transmission of differential clock signals is the differential clock cross-point voltage, commonly referred to as V_{OX}. V_{OX} indicates how much is the difference between the cross over point and the average value of the differential signal.

### BRIEF DESCRIPTION OF THE DRAWINGS

The present disclosure is illustrated by way of example, and not by way of limitation, in the figures of the accompanying drawings.

FIG. 1 is a block diagram of a transmitter (TX) circuit with programmable phase distribution according to at least one embodiment.

FIG. 2A is a graph illustrating a differential clock signal with a first differential cross-point voltage ratio according to at least one embodiment.

FIG. 2B is a graph illustrating a differential clock signal with a second differential cross-point voltage ratio according to at least one embodiment.

FIG. 3 is a block diagram of a computing system having a host device and a memory system with a transmitter with programmable phase distribution according to at least one embodiment.

FIG. 4 is a graph illustrating a differential clock cross-point ratio according to at least one embodiment.

FIG. 5A is a schematic diagram of differential driver circuits of a transmitter with programmable phase distribution according to at least one embodiment.

FIG. 5B illustrates a schematic diagram and a signal diagram corresponding to a first set of phases for voltage-mode drivers with pull-up transistors according to at least one embodiment.

FIG. 5C illustrates a schematic diagram and a signal diagram corresponding to a second set of phases for voltage-mode drivers with pull-down transistors according to at least one embodiment.

FIG. 6 is a block diagram of a computing system having a host device and a memory system with a transmitter with programmable phase distribution according to at least one embodiment.

FIG. 7 is a block diagram of a differential driver architecture for a transmitter with programmable phase distribution according to at least one embodiment.

FIG. 8A is a block diagram of a buffer device in a test environment to program a programmable phase distribution of a transmitter according to at least one embodiment.

FIG. 8B are plot diagrams of slew rate measurements and differential cross-point voltage measurements for a combination of values for a selection vector to program a transmitter with a programmable phase distribution according to at least one embodiment.

FIG. 9 is a flow diagram of a method of operating a buffer device with a transmitter having a programmable phase distribution according to at least one embodiment.

### DETAILED DESCRIPTION

Technologies for integrated circuit (IC) transmitter circuit with differential signal cross point voltage control are described. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure. Aspects and embodiments of the present disclosure provides independent control of Vox, a parameter in high-speed transmission. By using programmable phase distribution in the driver units, aspects and embodiments of the present disclosure can precisely tune Vox without affecting other critical parameters such as slew rate or duty cycle. This ensures optimized signal integrity at higher speeds and across various RON conditions. It also improves transient impedance behavior through phase distribution, further enhancing signal quality and overall system reliability.

As memory speeds increase and V_{OX} requirements become more stringent, aspects and embodiments of the present disclosure can provide the ability to control and improve Vox across all parts minimizes the Monte Carlo spread, resulting in more consistent performance. Additionally, aspects and embodiments of the present disclosure can allow Vox tuning post-silicon, reducing design time and accelerating product development cycles. Aspects and embodiments of the present disclosure can generate V_{OX} shmoo plots during automatic test equipment (ATE) testing. Aspects and embodiments of the present disclosure can use control registers for fine-tuning V_{OX} across different R_{ON} parameters.

Aspects and embodiments of the present disclosure can provide various advantages in performance like Vox, eye parameters and transient impedance power improvement, flexibility, etc. Aspects and embodiments of the present disclosure can provide better performance in terms of signal integrity, time and energy and a scalable solution.

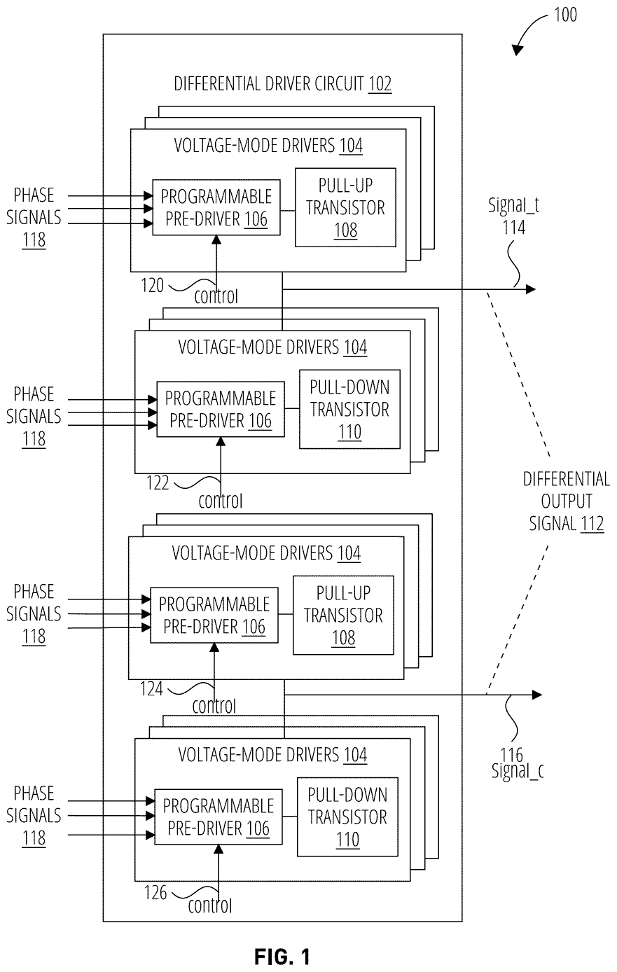

FIG. 1 is a block diagram of a TX circuit 100 with a programmable phase distribution according to at least one embodiment. The differential driver circuit 102 includes a differential driver circuit 102 to generate a differential output signal 112. The differential output signal 112 is made up of a signal 114 and a complementary signal 116. The signal 114 can be generated by one or more pairs of voltage-mode drivers 104. Some of the voltage-mode drivers 104 include pull-up transistors pull-up transistor 108, and others include pull-down transistors 110. Each of the voltage-mode drivers 104 include a programmable pre-driver 106 that can be individually controlled. The programmable pre-drivers 106 can be collectively controlled as a programmable phase distribution. The programmable phase distribution can be controlled, via the individual controls of the programmable pre-drivers 106, to adjust a differential cross-point parameter of the differential driver circuit 102. The programmable phase distribution can adjust a differential cross-point parameter, such as the differential cross-point ratio, of the differential driver circuit 102. Alternatively, the programable phase distribution can adjust a slew rate of the differential driver circuit 102. Alternatively, the programable phase distribution can adjust a transient output impedance of the differential driver circuit 102.

In at least one embodiment, each of the programmable pre-drivers 106 can be individually controlled using a control value or a control signal, as illustrated as control value/signal 120, control value/signal 122, control value/signal 124, and control value/signal 126 for four of the voltage-mode drivers 104. It should be noted that other control value/signals can be used for the other voltage-mode drivers 104 of the differential driver circuit 102. The number of voltage-mode drivers 104 can be a fixed number or can be programmable. For example, the number of voltage-mode drivers 104 can be selected based on a R_{ON} parameter. Once the number of voltage-mode drivers 104 are selected, the programmable pre-drivers 106 can be programmed by the individual control values/signals. Each of the programmable pre-drivers 106 receives phase signals 118. The phase signals 118 can be derived from a clock signal, for example. Based on the control value/signal of the respective voltage-mode driver 104, the programmable pre-driver 106 can select one of the phase signals 118. The selected number of voltage-mode drivers 104 with the pull-up transistor 108 and the corresponding voltage-mode drivers 104 with the pull-down transistors 110 can generate the signal 114 (e.g., signal_t). The same selected number of voltage-mode drivers 104 with the pull-up transistor 108 and the corresponding voltage-mode drivers 104 with the pull-up transistors 108 can generate the complementary signal 116 (e.g., signal_c). The signal 114 and the complementary signal 116 make up the differential output signal 112.

In at least one embodiment, the differential driver circuit 102 is a differential clock driver circuit, and the differential output signal 112 is a differential clock signal, for example, for a serial link transmitter output. In another, the differential output signal 112 is a differential data signal.

In at least one embodiment, the differential driver circuit 102 is coupled to a register that stores a set of values corresponding to the programmable phase distribution, each value corresponding to the programmable phase of one of the voltage-mode drivers 104. In at least one embodiment, different combination of values can be stored for different parameters, such as different R_{ON} parameters. For a first R_{ON} parameter, the register can store a first combination of values for a first number of voltage-mode drivers 104 and, for a second R_{ON} parameter, the register can store a second combination of values for a second number of voltage-mode drivers 104. The first number and the second number can be the same number or a different number. For example, in at least one embodiment, the register can store i) a first set of values corresponding to the programmable phase distribution for a first output impedance (R_{ON}) parameter of the differential driver circuit 102, and ii) a second set of values corresponding to a second programmable phase distribution for a second R_{ON} parameter of the differential driver circuit 102.

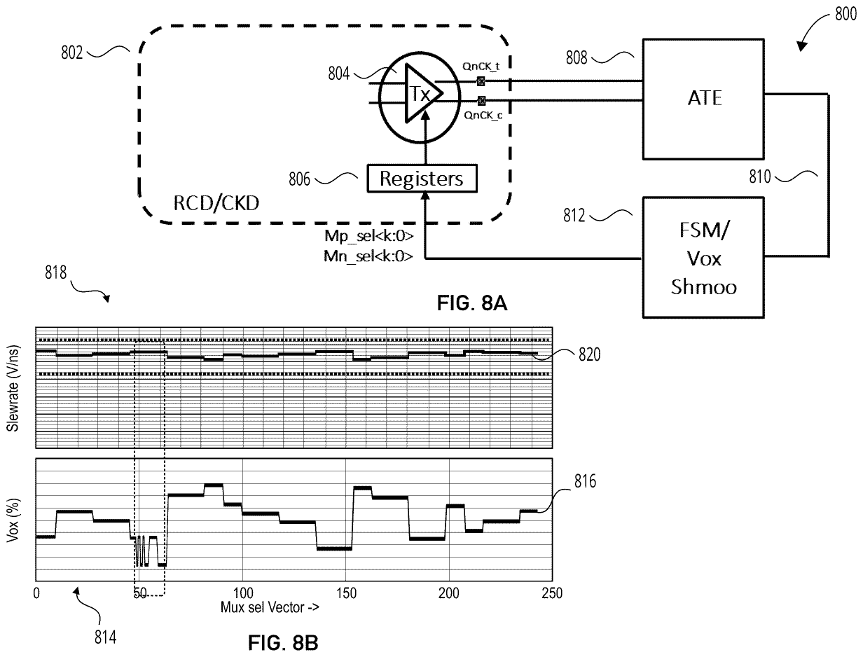

In at least one embodiment, the values can be automatically calibrated by a digital eye monitoring system coupled to the TX circuit 100. Additional details are described below with respect to FIG. 8A and FIG. 8B.

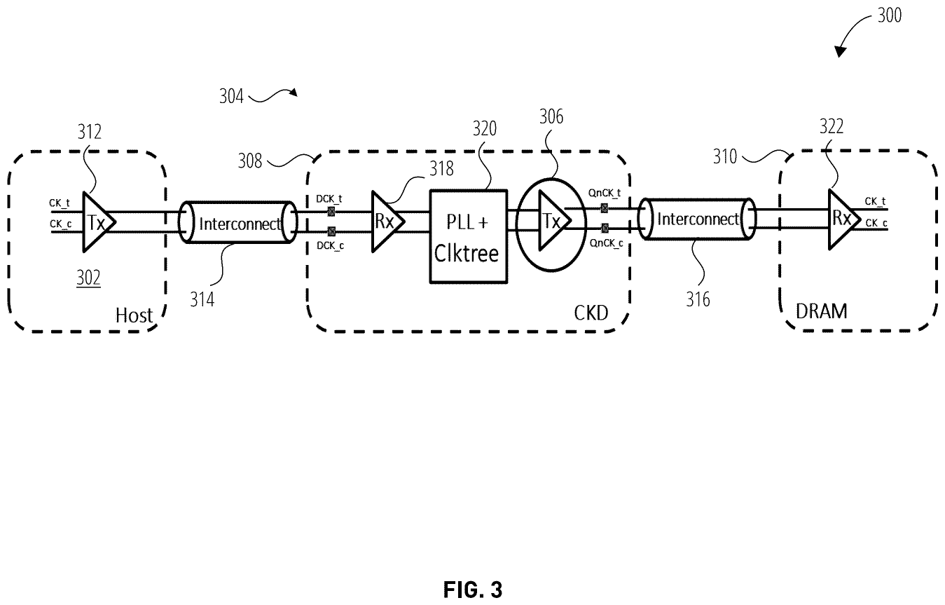

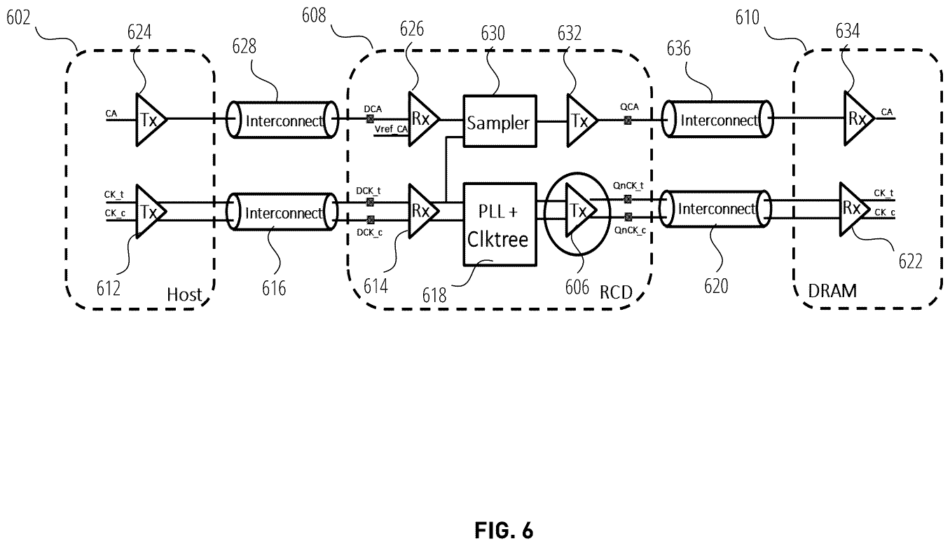

In at least one embodiment, the TX circuit 100 resides in a buffer device, such as a Register Clock Driver (RCD) device illustrated and described in FIG. 6 or a Clock Driver (CKD) device illustrated and described in FIG. 3. In another embodiment, the TX circuit 100 can reside in a host device or other types of integrated circuit devices having a differential driver circuit.

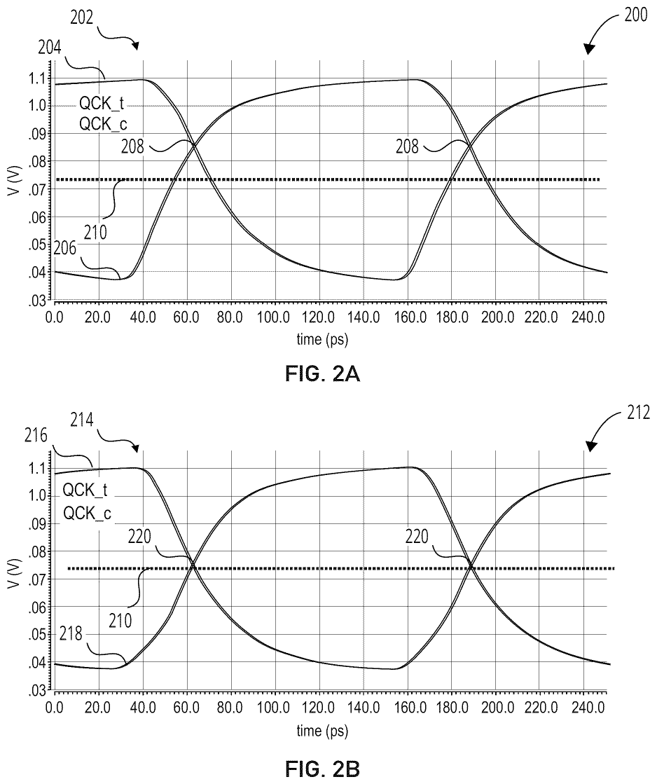

As described above, the TX circuit 100 generates the differential output signal 112. Timing diagrams of FIG. 2A and FIG. 2B illustrates how the programmable phase distribution can be individually controlled

FIG. 2A is a graph 200 illustrating a differential clock signal 202 with a first differential cross-point voltage ratio according to at least one embodiment. The differential clock signal 202 can be generated by the differential driver circuit 102 described above. Alternatively, the differential clock signal 202 can represent a differential output signal that is not a clock signal. The differential clock signal 202 is made up of a first signal 204 (QCK_t) and a complementary second signal 206 (QCK_c). As described above, the points where first signal 204 and the second signal 206 intersect is the cross over point, and V_{OX} indicates how much difference there is between the cross over point and the average value of the differential signal. More specifically, the cross over point is the point where the rising and falling edges of the differential signal cross each other. As illustrated in FIG. 2A, the first signal 204 and the second signal 206 cross at a cross-point voltage 208, which is above a target voltage 210. The target voltage 210 can be a common-mode voltage, which is given by the following Equation 1:

$${V}_{OCM} = \frac{{V}_{P} + {V}_{N}}{2} ,$$

where V_{P} is the positive (or non-inverting) differential signal voltage, and V_{N} is the negative (inverting) differential signal voltage. In another implementation, the target voltage 210 can be expressed in the following Equation 2:

$${V}_{OCM} = avg ( QCK\_t + QCK\_c ) / 2$$

The V_{OX} parameter can be expressed as a differential cross-point voltage ratio, which describes the ratio of the voltage at the “cross point” (the point where the rising and falling edges of a differential signal cross each other) with respect to the average of a nominal signal swing (i.e., the total peak-to-peak differential signal swing (maximum difference between the high and low voltage levels of the differential signal). In at least one embodiment, the V_{OX} ratio can be expressed in the following Equation 3:

$${V}_{OX} \_KCK \_Ratio = ( \frac{\vert {V}_{OX} \_CK \vert}{\vert {V}_{RMS} \vert} ) * 100 \% ,$$

where V_{RMS}=RMS (QCK_t voltage−QCK_c voltage). In other implementations, the V_{OX} parameter can be expressed as a difference (or the delta) between the cross-point voltage 208 and the target voltage 210. Although the cross-point voltage 208 is illustrated above the target voltage 210, in other cases, the cross-point voltage can be below the target voltage 210.

In at least one embodiment, as described above, the programmable pre-drivers 106 of the differential driver circuit 102 can be calibrated, programmed or otherwise individually controlled to adjust the programmable phase distribution of the differential driver circuit 102. That is, programmable pre-driver 106 can be controlled to adjust the first differential cross-point ratio illustrated in FIG. 2A to have a second differential cross-point voltage ratio, as illustrated in FIG. 2B.

FIG. 2B is a graph 212 illustrating a differential clock signal 214 with a second differential cross-point voltage ratio according to at least one embodiment. The differential clock signal 214 can be generated by the differential driver circuit 102 described above while programming the individual programmable pre-drivers 106 to adjust the first differential cross-point voltage ratio to the second differential cross-point voltage ratio. The differential clock signal 214 is made up of a first signal 216 and a second signal 218. As illustrated in FIG. 2B, the first signal 216 and the second signal 218 cross at a cross-point voltage 220, which is slightly above or at the target voltage 210. In other words, the slew rate rise and the slew rate fall match at approximately 27V/ns with a V_{OX} of 2%, as opposed to the slew rate rise and the slew rate fall matching at approximately 26V/ns with a V_{OX} of 15% as illustrated in FIG. 2A. As illustrated in FIG. 2B, the programmable pre-drivers 106 of the differential driver circuit 102 can be individually controlled to adjust the programmable phase distribution, which adjust the V_{OX} parameter. In these examples of FIG. 2A and FIG. 2B, the V_{OX} parameter is improved by adjusting it closer to the target voltage 210. In other words, the programmable pre-drivers 106 can be individually controlled to adjust the differential cross-point voltage ratio. The programmable pre-drivers 106 can be used to control other parameters, such as slew rate rise (V/ns), slew rate fall (SRF (V/ns), duty cycle (%), delay (ps), power (mA), differential cross-point voltage, or the like.

As described above, the differential driver circuit 102 can be implemented in a Clock Driver device, such as illustrated and described below with respect to FIG. 3.

FIG. 3 is a block diagram of a computing system 300 having a host device 302 and a memory sub-system 304 with a transmitter 306 (also referred to herein as transmitter circuit) with programmable phase distribution according to at least one embodiment. The memory sub-system 304 can be a DDR5 memory sub-system used in client computing.

The computing system 300 can be a set of integrated circuit components that work together to process, store, and manage data. The computing system 300 can include hardware, software, and networking resources, all designed to perform various computational tasks efficiently. The computing system 300 can include various hardware, such as a central processing unit (CPU), a graphics processing unit (GPU), etc., coupled to the memory sub-system 304. The computing system 300 can also include other components, such as storage devices (e.g., hard drives, solid-state drives, etc.), input/output devices (e.g., keyboard, mouse, display screen), and networking components (network cards, routers). The computing system 300 can also include a fabric switch coupled between the different components. The computing system 300 can include software, such as programs and/or applications, that run on the CPU and/or GPU to perform specific tasks. The software can include an operating system (OS) to provide essential services for managing hardware resources and facilitating software execution, applications, firmware, etc.

The host device 302 can include a CPU that is the primary component of the computing system 300 that performs most of the processing tasks. The CPU interprets and executes instructions from the memory sub-system 304 and carries out basic arithmetic, logical, control, and input/output operations specified by the instructions. The CPU can include one or more cores, which allows for parallel processing and improved multitasking capabilities. The CPU can delegate processing jobs to the GPU. The GPU can be primarily used in computing systems for tasks that require high-speed parallel processing, such as graphics rendering, machine learning, and scientific simulations. GPU possesses a highly parallel structure with thousands of cores designed to handle multiple operations simultaneously. This architecture enables the GPU to efficiently process large sets of data in real-time, which is crucial for graphics rendering and complex computational tasks. The GPU can have dedicated memory in the memory sub-system 304. Besides graphical processing, the GPU can be used for general-purpose computing tasks such as deep learning, scientific simulations, and data analytics due to their high parallelism and computational power. GPUs come in various forms, including integrated graphics chips found within the CPU package or dedicated discrete GPU cards that can be added into a computer system's motherboard via PCI Express (PCIe) slots. As illustrated in FIG. 3, the computing system 300 can include a single host device 302, but in other embodiments, the computing system 300 can include multiple host devices, such as multiple CPUs and multiple GPUs.

The memory sub-system 304 can include a Clock Driver device 308 and one or more DRAM devices 310. In this embodiment, the transmitter 306 with programmable phase distribution is implemented in the Clock Driver device 308. The Clock Driver device 308 is used in buffering clock signals from the host device 302 to the one or more DRAM devices 310. In other embodiments, the transmitter with programmable phase distribution can be implemented in other transmitters, such as a transmitter 312 of the host device 302. In other embodiments, the transmitter can be used for transmitting data signals.

In the illustrated embodiment, the transmitter 312 of the host device 302 can connect to a receiver 318 (also referred to herein as receiver circuit) of the Clock Driver device 308 over an interconnect 314. The Clock Driver device 308 can include a phase-locked loop (PLL) and clock tree 320. A PLL can be used to control the frequency, phase, and stability of the incoming clock signal. The PLL can lock onto the input clock signal and generates a synchronized, high-quality output clock with specific desired properties. The clock tree is a network used to distribute the clock signal to various parts of a chip or system, ensuring synchronized operation across all components. The transmitter 306 can be used to transmit a differential clock signal to the one or more DRAM devices 310 over an interconnect 316. The one or more DRAM devices 310 can include a receiver 322 to receive the differential clock signal from the transmitter 306.

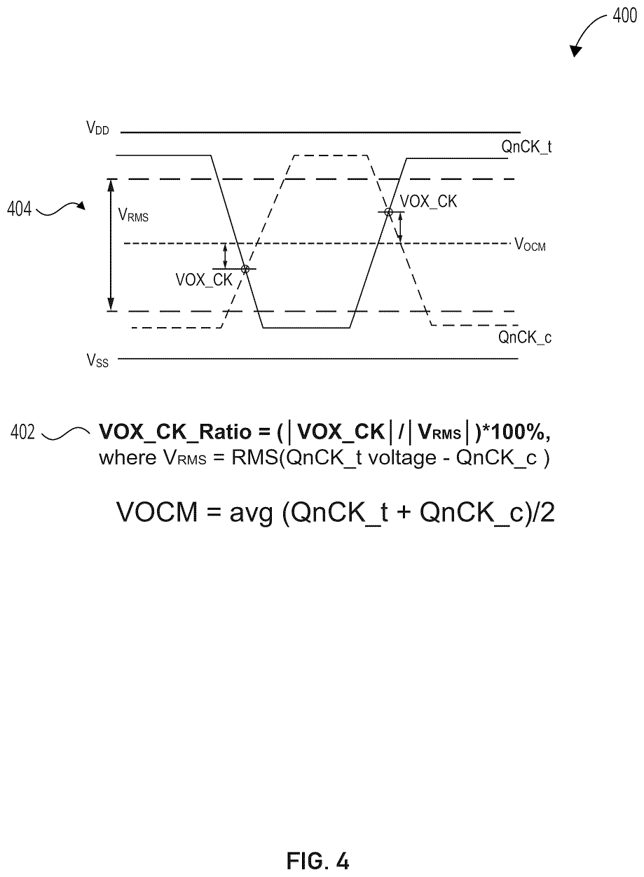

As described above, the transmitter 306 can include the differential driver circuit 102 with multiple voltage-mode drivers, each with the programmable pre-driver 106 that can be individually controlled to adjust the programmable phase distribution of the transmitter 306. The transmitter 306 can be programmed to adjust the differential cross-point voltage ratio, as described above. For example, some standards' specifications can specify a maximum differential cross-point parameter (e.g., 10% or 20%) for specific speeds or models. The transmitter 306 can adjust the individual phases of the voltage-mode drivers to achieve a differential cross-point voltage ratio that is within the standards' specifications. A graph illustrating a V_{OX} clock ratio is illustrated and described below with respect to FIG. 4.

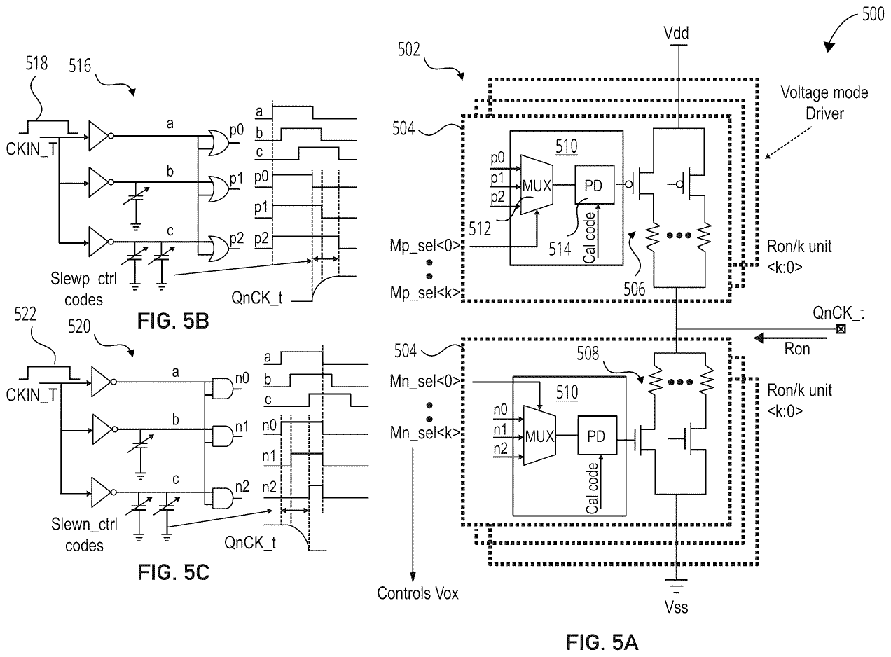

FIG. 4 is a graph 400 illustrating a V_{OX} clock ratio 402 according to at least one embodiment. The V_{OX} clock ratio 402 can be determined using Equation 2 and Equation 3. The V_{OX} clock ratio 402 can be provided as a formal definition of the differential clock cross-point voltage (Vox), as specified by JEDEC. The V_{OX} clock ratio 402 can be determined from differential cross-point voltage measurements (labeled VOX_CK) (also referred to as V_{OX} measurements) of a differential clock signal 404. As described in more detail below with respect to FIG. 8A and FIG. 8B, a testing device or process can generate test data including the differential cross-point voltage measurements of the transmitter 306 by sweeping through a plurality of different combinations of values of a selection vector, representing a programmable phase distribution of the transmitter 306. As described above, the transmitter 306 includes voltage-mode drivers, each having a pull-up transistor or a pull-down transistor, and a pre-driver circuit with a programmable phase that is individually controlled by a value of the selection vector. Additional details of the voltage-mode drivers are illustrated and described below with respect to FIG. 5A, FIG. 5B, and FIG. 5C.

The testing device or process can identify, using the test data, a combination of values from the plurality of different combinations that results in the lowest differential cross-point voltage measurements. The testing device or process can then store the combination of values in a register of the Clock Driver device 308 that controls the programmable phases of the pre-driver circuits of the transmitter 306. In this manner, the transmitter 306 can be programmed to adjust the V_{OX} clock ratio 402, such as to be within the standards' specifications. In an embodiment and on-chip calibration circuit can be used to automatically adjust the programmable phases of the pre-driver circuits of the transmitter 306.

FIG. 5A is a schematic diagram of differential driver circuits 502 of a transmitter 500 with programmable phase distribution according to at least one embodiment. The transmitter 500 can be the transmitter 306 of FIG. 3. The transmitter 500 can be the transmitter 606 of FIG. 6. The differential driver circuits 502 can be similar to the differential driver circuit 102 of FIG. 1. Each of the differential driver circuits 502 includes a pair of voltage-mode drivers 504. Each voltage-mode driver 504 includes a pull-up transistor 506 or a pull-down transistor 508 and a pre-driver circuit with programmable phase 510. Each pre-driver circuit with programmable phase 510 can include a multiplexer 512 and a pre-driver 514. The multiplexer 512 can receive multiple phase signals (p0, p1, and p2 in the illustrated embodiment). The multiplexer 512 can also receive a control signal (or control value) that selects one of the phase signals to output to the pre-driver 514. Each of the pre-driver circuit with programmable phase 510 can be individually controlled to control the programmable phase distribution of the transmitter 500. The phase signals can be generated and provided by phase generator circuits 516 and 520, such as illustrated in FIG. 5B and FIG. 5C.

FIG. 5B illustrates a schematic diagram and a signal diagram corresponding to a first set of phases for voltage-mode drivers with pull-up transistors according to at least one embodiment. In a phase generator circuit 516, an input clock 518 drives a delay line followed by logic cells to generate varying phases, including a first phase (p0), a second phase (p1), and a third phase (p2). The varying phases can control the timing of R_{ON} unit transitions, thereby enabling slew rate control. These three phases can be provided to the multiplexer 512 to control a rising edge of a clock signal (QnCK_t).

FIG. 5C illustrates a schematic diagram and a signal diagram corresponding to a second set of phases for voltage-mode drivers with pull-down transistors according to at least one embodiment. In a phase generator circuit 520, an input clock 522 drives a delay line followed by logic cells to generate varying phases, including a first phase (n0), a second phase (n1), and a third phase (n2). The varying phases can control the timing of R_{ON} unit transitions, thereby enabling slew rate control. These three phases can be provided to the multiplexer 512 to control a falling edge of the clock signal (QnCK_t). Similar circuits can be used for a rising edge and a falling edge of a complementary clock signal (QnCK_c).

The R_{ON} unit is one differential driver circuit 502 (i.e., a pair of voltage-mode drivers). Each R_{ON} unit can be selected by control values/signals (e.g., Ron/k unit <k:0>). The R_{ON} parameter can be achieved by selectively enabling different combination of differential driver circuits 502 (e.g., driver legs) using R_{ON} control values/signals. Calibration control can adjust each differential driver circuit's output impedance based on ZQ calibration (i.e., an impedance adjustment based on a control loop that employs an external precision resister referred to as ZQ). Each differential driver circuits 502 (e.g., driver's leg) is equipped with a pre-driver 514 and a pre-driver circuit with programmable phase 510 that includes a multiplexer 512 to select between different phases, which can be programmed independently for each differential driver circuits 502 (e.g., each driver leg). This programmability directly influences the V_{OX} parameter.

As described above, the differential driver circuit 102 can be implemented in an RCD device, such as illustrated and described below with respect to FIG. 6.

FIG. 6 is a block diagram of a computing system 600 having a host device 602 and a memory sub-system 604 with a transmitter 606 (also referred to herein as transmitter circuit) with programmable phase distribution according to at least one embodiment. The memory sub-system 604 can be a DDR5 memory system used in a server computing system. The memory sub-system 604 can include an RCD device 608 and one or more DRAM device(s) 610. In this embodiment, the transmitter 606 with programmable phase distribution is implemented in the RCD device 608. The RCD device 608 is used in buffering clock signals from the host device 602 to the one or more DRAM device(s) 610. In other embodiments, the transmitter with programmable phase distribution can be implemented in other transmitters, such as a transmitter 612 of the host device 602. In other embodiments, the transmitter can be used for transmitting data signals.

In the illustrated embodiment, the transmitter 612 of the host device 602 can connect to a receiver 614 (also referred to herein as receiver circuit) of the RCD device 608 over an interconnect 616. The RCD device 608 can include a PLL and clock tree 618. A PLL can be used to manipulate the frequency, phase, and stability of the incoming clock signal. The PLL can lock onto the input clock signal and generates a synchronized, high-quality output clock with specific desired properties. The clock tree is a network used to distribute the clock signal to various parts of a chip or system, ensuring synchronized operation across all components. The transmitter 606 can be used to transmit a differential clock signal to the one or more DRAM device(s) 610 over an interconnect 620. The one or more DRAM device(s) 610 can include a receiver 622 to receive the differential clock signal from the transmitter 606.

In this embodiment, the host device 602 also includes a transmitter 624 to send a command and address (CA) signal (or alternatively a data signal). The CA signal can be a single-ended signal. Alternatively, the transmitter 624 can be a differential transmitter that sends a differential signal. The RCD device 608 includes a receiver 626 that receives the CA signal over an interconnect 628. The RCD device 608 includes a sampler 630 (also referred to as sampler circuit). The sampler 630 can sample the CA signal using a portion of the differential clock fed to the PLL and clock tree 618. The sampled CA signal can be transmitted by a transmitter 632 to a receiver 634 of the DRAM device(s) 610 over an interconnect 636.

As described above, the transmitter 606 can include the differential driver circuit 102 with multiple voltage-mode drivers, each with the programmable pre-driver 106 that can be individually controlled to adjust the programmable phase distribution of the transmitter 606. The transmitter 606 can be programmed to adjust the differential cross-point voltage ratio, as described above. For example, some standards' specifications can specify a maximum differential cross-point parameter (e.g., 10% or 20%) for specific speeds or models. The transmitter 606 can adjust the individual phases of the voltage-mode drivers to achieve a differential cross-point voltage ratio that is within the standards' specifications.

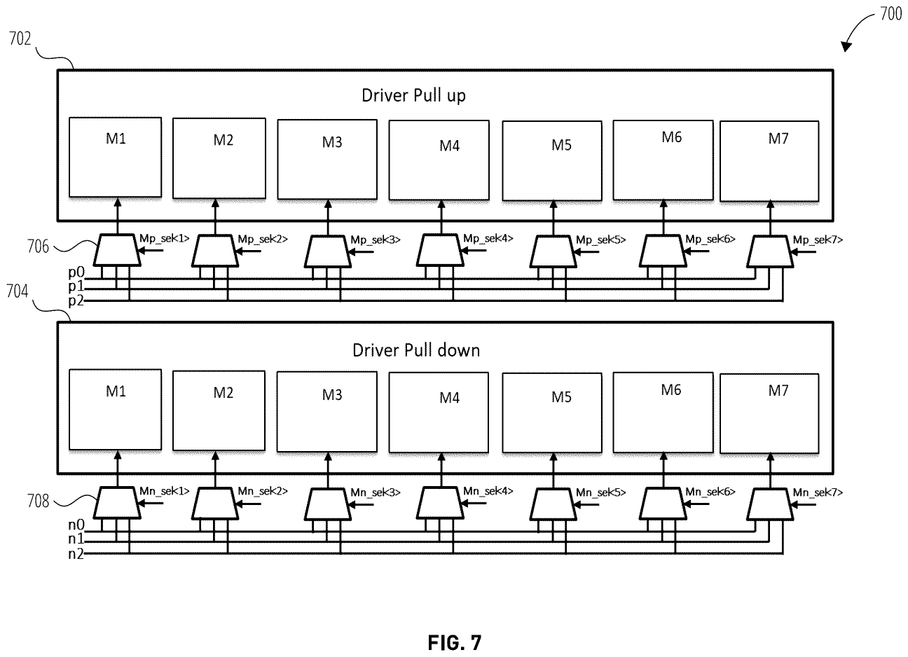

FIG. 7 is a block diagram of a differential driver architecture for a transmitter 700 with programmable phase distribution according to at least one embodiment. The transmitter 700 includes a set of pull-up drivers 702 and a set of pull-down drivers 704. The pull-up drivers 702 and pull-down drivers 704 can include the voltage-mode drivers and optional pre-drivers as described above. The pull-up drivers 702 can have varying output impedances Similarly, the pull-down drivers 704 can include varying output impedances.

The number of pull-up drivers 702 and pull-down drivers 704 can be a fixed number or can be programmable. For example, the number of pull-up drivers 702 and pull-down drivers 704 can be selected based on a output impedance parameter (R_{ON}). For different R_{ON} parameters, different combinations of the pull-up drivers 702 and pull-down drivers 704 can be selected. For example, for a first R_{ON} parameter, all seven of the illustrated pull-up drivers 702 and the pull-down drivers 704 can be selected. For a different R_{ON} parameter, less than the seven pull-up drivers 702 and pull-down drivers 704 are selected. Once the number of pull-up drivers 702 and pull-down drivers 704 have been selected, each of the selected pull-up drivers 702 and pull-down drivers 704 can be controlled with one of the multiple phases, as described above. That is, each of the pull-up drivers 702 and pull-down drivers 704 are programmable to adjust a differential cross-point parameter, such as the V_{OX} parameter.

In this embodiment, each pull-up drivers 702 is coupled to a multiplexer 706 that receives multiple phases and a control signal or value that selects one of the multiple phases for the corresponding pull-up drivers 702. Similarly, each pull-down drivers 704 is coupled to a multiplexer 706 that receives multiple phases and a control signal or value that selects one of the multiple phases for the corresponding pull-down drivers 704. The control signals/values can be independently controlled for each of the pull-up drivers 702 and pull-down drivers 704. The selected number of pull-up drivers 702 and pull-down drivers 704 can generate a one of the two signals that make up the differential signal. The same selected number of pull-up drivers and pull-down drivers can be used to generate the other complementary signal. By individually controlling the phase distribution across the selected number of pull-up drivers 702 and pull-down drivers 704, the differential cross-point parameter of the differential signal can be adjusted. This allows the differential cross-point parameter to be optimized for a given device, such as illustrated in FIG. 8A.

FIG. 8A is a block diagram of a buffer device 802 in a test environment 800 to program a programmable phase distribution of a transmitter 804 according to at least one embodiment. The test environment 800 can be used for a post silicon V_{OX} parameter correction calibration. In the test environment 800, an automatic test equipment 808 (ATE) can be coupled to the buffer device 802. The transmitter 804 can generate a differential output signal that is measured by the ATE 808. The settings of the transmitter 804 can be varied to generate test data 810 for different settings. The test data 810 can include V_{OX} measurements 816 (i.e., differential cross-point voltage measurements) and slew rate measurements 820 of the transmitter 804. This can be done by sweeping through different combinations of values of a selection vector. The selection vector represents a programmable phase distribution of the transmitter 804. As described herein, the transmitter 804 includes programmable phases of individual pull-up and pull-down driver legs. The programmable phase is individual controlled by a value of the selection vector. For example, a pull-down driver that includes seven driver legs can have seven values that control the individual phases of the seven driver legs of the pull-up driver. Similarly, a pull-down driver that includes seven driver legs can have seven values that control the individual phases of the seven driver legs of the pull-down driver. Programming logic 812 can be used to identify, using the test data 810, a combination of values from the plurality of different combinations that results in the lowest V_{OX} measurements 816, for example. The programming logic 812 can select the values that correspond to the lowest V_{OX} measurements where the slew rate measurements 820 are within a specified tolerance, for example. In at least one embodiment, the programming logic 812 can be a finite state machine (FSM) that steps through the different combinations and generates V_{OX} and slew rate shmoo plots to determine which combination should be selected for a given R_{ON} parameter. Example shmoo plots are illustrated in FIG. 8B. This process can be repeated for other R_{ON} parameters. Once the combination of values is determined, the values can be stored in one or more registers 806 of the buffer device 802. The one or more registers 806 control the programmable phases of the pull-up and pull-down drivers of the transmitter 804.

FIG. 8B are plot diagrams of slew rate measurements and differential cross-point voltage measurements for a combination of values for a selection vector to program a transmitter with a programmable phase distribution according to at least one embodiment. FIG. 8B includes a shmoo plot 814 of V_{OX} measurements 816 and a shmoo plot 818 of slew rate measurements 820. As illustrated in the shmoo plot 814 and shmoo plot 818, the values corresponding to the lowest V_{OX} measurements 816 can be selected as the slew rate measurements 820 are within a tolerance range. These values can be stored in the registers 806 of the buffer device 802, as the optimal settings for the transmitter 804.

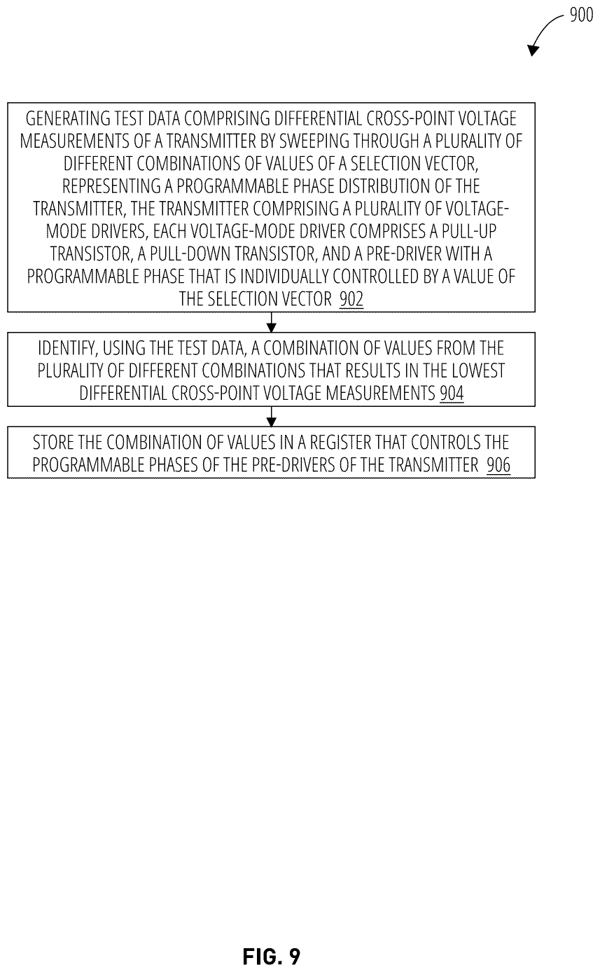

FIG. 9 is a flow diagram of a method 900 of operating a buffer device with a transmitter having a programmable phase distribution according to at least one embodiment. The method 900 can be performed by processing logic that may comprise hardware (e.g., circuitry, dedicated logic, programmable logic, microcode, etc.), software (e.g., instructions run on a processing device to perform hardware simulation), or a combination thereof. In one embodiment, the method 900 is performed by a test device, including one or more processing units, such as CPUs, GPUs, or the like, in connection with a transmitter with programmable phase distribution as described herein.

Referring to FIG. 9, the method 900 begins by the processing logic generating test data comprising differential cross-point voltage measurements of a transmitter by sweeping through a plurality of different combinations of values of a selection vector, representing a programmable phase distribution of the transmitter (block 902). The transmitter includes a plurality of voltage-mode drivers, each voltage-mode driver comprises a pull-up transistor, a pull-down transistor, and a pre-driver with a programmable phase that is individually controlled by a value of the selection vector. The transmitter can also include pull-up drivers and pull-down drivers coupled to a multiplexer that is individually controlled to select a programmable phase of each of the pull-up and pull-down drivers. At block 904, the processing logic identifies, using the test data, a combination of values from the plurality of different combinations that results in the lowest differential cross-point voltage measurements. At block 906, the processing logic stores the combination of values in a register that controls the programmable phases of the pre-drivers of the transmitter.

In a further embodiment, the method 900 can be repeated for multiple R_{ON} parameters. In at least one embodiment, before generating the test data, the processing logic identifies a first output impedance (R_{ON}) parameter of the transmitter. The combination of values stored in the register is associated with the first R_{ON} parameter. The processing logic identifies a second R_{ON} parameter of the transmitter. The processing logic generates second test data of the transmitter and identifies, using the second test data, a second combination of values that results in the lowest differential cross-point voltage measurements. The processing logic stores the second combination of values in the register. The second combination of values is associated with the second R_{ON} parameter.

It is to be understood that the above description is intended to be illustrative and not restrictive. Many other implementations will be apparent to those of skill in the art upon reading and understanding the above description. Therefore, the disclosure scope should be determined with reference to the appended claims, along with the full scope of equivalents to which such claims are entitled.

In the above description, numerous details are set forth. It will be apparent, however, to one skilled in the art that the aspects of the present disclosure may be practiced without these specific details. In some instances, well-known structures and devices are shown in block diagram form rather than in detail to avoid obscuring the present disclosure.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to the desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

However, it should be borne in mind that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving,” “determining,” “selecting,” “storing,” “setting,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general-purpose computer selectively activated or reconfigured by a computer program stored in the computer. Such a computer program may be stored in a computer-readable storage medium, such as, but not limited to, any type of disk, including floppy disks, optical disks, CD-ROMs, and magnetic-optical disks, read-only memories (ROMs), random access memories (RAMs), erasable programmable ROMs (EPROMs), electrically erasable programmable ROMs (EEPROMs), magnetic or optical cards, or any type of media suitable for storing electronic instructions, each coupled to a computer system bus.

The algorithms and displays presented herein are not inherently related to any particular computer or other apparatus. Various general-purpose systems may be used with programs in accordance with the teachings herein, or it may prove convenient to construct more specialized apparatuses to perform the required method steps. The required structure for a variety of these systems will appear as set forth in the description. In addition, aspects of the present disclosure are not described with reference to any particular programming language. It will be appreciated that a variety of programming languages may be used to implement the teachings of the present disclosure as described herein.

Aspects of the present disclosure may be provided as a computer program product, or software, that may include a machine-readable medium having stored thereon instructions, which may be used to program a computer system (or other electronic devices) to perform a process according to the present disclosure. A machine-readable medium includes any procedure for storing or transmitting information in a form readable by a machine (e.g., a computer). For example, a machine-readable (e.g., computer-readable) medium includes a machine (e.g., a computer) readable storage medium (e.g., read-only memory (“ROM”), random access memory (“RAM”), magnetic disk storage media, optical storage media, flash memory devices, etc.).

What is claimed is:

1. A transmitter (TX) circuit comprising:
a differential driver circuit to generate a differential output signal, wherein the differential driver circuit comprises a programmable phase distribution to adjust a differential cross-point ratio of the differential driver circuit, wherein the differential driver circuit comprises a plurality of voltage-mode drivers, each voltage-mode driver comprises a pull-up transistor and a pull-down transistor and a pre-driver circuit with a programmable phase that is individually controlled for each voltage-mode driver such that the plurality of voltage-mode drivers collectively adjust the differential cross-point ratio.

2. The TX circuit of claim 1, wherein the programmable phase distribution is to adjust a slew rate of the differential driver circuit.

3. The TX circuit of claim 1, wherein the programmable phase distribution is to adjust a transient output impedance of the differential driver circuit.

4. The TX circuit of claim 1, further comprising a register to store a plurality of values corresponding to the programmable phase distribution, each value corresponding to the programmable phase of one of the plurality of voltage-mode drivers.

5. The TX circuit of claim 4, wherein the plurality of values are automatically calibrated by a digital eye monitoring system coupled to the TX circuit.

6. The TX circuit of claim 1, wherein the differential driver circuit is a differential clock driver circuit, and wherein the differential output signal is a differential clock signal.

7. The TX circuit of claim 1, wherein the differential output signal is a differential data signal.

8. The TX circuit of claim 1, wherein the TX circuit resides in a Register Clock Driver (RCD) device or a Clock Driver (CKD) device.

9. The TX circuit of claim 1, further comprising:
a register to store i) a first set of values corresponding to the programmable phase distribution for a first output impedance (R_{ON}) parameter of the differential driver circuit, and ii) a second set of values corresponding to a second programmable phase distribution for a second R_{ON} parameter of the differential driver circuit.

10. A buffer device comprising:
a transmitter to generate a differential clock signal, the transmitter comprising a plurality of voltage-mode drivers, each voltage-mode driver comprises a pull-up transistor, a pull-down transistor, and a pre-driver circuit with a programmable phase that is individually controlled for each voltage-mode driver such that the plurality of voltage-mode drivers collectively adjust a differential cross-point parameter of the transmitter.

11. The buffer device of claim 10, wherein differential cross-point parameter is a differential clock cross-point ratio.

12. The buffer device of claim 10, wherein the programmable phase is individually controlled to adjust a slew rate parameter of the transmitter.

13. The buffer device of claim 10, wherein the programmable phase is individually controlled to adjust a transient output impedance of the transmitter.

14. The buffer device of claim 10, wherein the buffer device is a Register Clock Driver (RCD) device.

15. The buffer device of claim 10, wherein the buffer device is a Clock Driver (CKD) device.

16. The buffer device of claim 10, further comprising a register to store a plurality of values, each value corresponding to the programmable phase of one of the plurality of voltage-mode drivers.

17. The buffer device of claim 10, further comprising a register to store i) a first set of values corresponding to a programmable phase distribution for a first output impedance (R_{ON}) parameter of the transmitter, and ii) a second set of values corresponding to a second programmable phase distribution for a second R_{ON} parameter of the transmitter.

18. The buffer device of claim 17, wherein the first set of values and the second set of values are automatically calibrated by a digital eye monitoring system coupled to the buffer device.

19. A method of operating a buffer device comprising a transmitter, the transmitter comprising a plurality of voltage-mode drivers, each voltage-mode driver comprises a pull-up transistor, a pull-down transistor, and a pre-driver circuit with a programmable phase that is individually controlled by a value of the selection vector, the method comprising:
generating test data comprising differential cross-point voltage measurements of the transmitter by sweeping through a plurality of different combinations of values of a selection vector, representing a programmable phase distribution of the transmitter;
identifying, using the test data, a combination of values from the plurality of different combinations that results in the lowest differential cross-point voltage measurements; and
storing the combination of values in a register that controls the programmable phases of the pre-driver circuits of the transmitter.

20. The method of claim 19, further comprising:
before generating the test data, identifying a first output impedance (R_{ON}) parameter of the transmitter, wherein the combination of values stored in the register is associated with the first R_{ON} parameter;
identifying a second R_{ON} parameter of the transmitter;
generating second test data of the transmitter;
identifying, using the second test data, a second combination of values that results in the lowest differential cross-point voltage measurements; and
storing the second combination of values in the register, wherein the second combination of values is associated with the second R_{ON} parameter.
